(19) United States
(12) Patent Application Publication
(10) Pub. No.: US 2007/0090875 A1
(43) Pub. Date: Apr. 26, 2007

(54) Feedback circuit for an operational amplifier, a current to voltage converter including such a circuit and a digital to analog converter including such a circuit

(75) Inventors: Roderick C. McLachlan, Edinburgh (GB); Alan Gillespie, East Lothian (GB); Teng-Hee Lee, Edinburgh (GB)

Correspondence Address: WOLF GREENFIELD & SACKS, PC, FEDERAL RESERVE PLAZA, 600 ATLANTIC AVENUE, BOSTON, MA, 02210-2206, US

(73) Assignee: Analog Devices, Inc.

(21) Appl. No.: 11/256,714

(22) Filed: Oct. 24, 2005

(51) Int. Cl. H03F 1/36

(52) U.S. Cl. 330/86

(57) ABSTRACT

A feedback circuit for an operational amplifier is provided, the circuit comprising a first impedance element in a current flow path between an output of the operational amplifier and a first node, wherein a plurality of impedance elements are, in response to a control signal, selectively connectable either between the first node and a first input of the operational amplifier, or between the first node and a further node, and the further node and the first input of the operational amplifier are at the same potential such that a voltage at the first node is independent of the control signal.

### FIELD OF THE INVENTION

The present invention relates to a feedback circuit for an operational amplifier, and such a circuit finds application in current to voltage converters as may be found, for example, in digital to analog converters.

### BACKGROUND OF THE INVENTION

It is often necessary to fabricate high accuracy analog integrated circuits. Generally it is desirable to be able to control the gain of such a circuit or its transfer characteristic when performing current to voltage conversion or voltage to current conversion.

It is known to use thin film resistors in such high accuracy analog integrated circuits because of their accuracy and stability over temperature and with respect to time. However variations and imperfections in the fabrication process mean that adjustments may be needed to the resistance provided by these resistors. Often these resistors are laser trimmed to improve their accuracy. However laser trimming has several disadvantages. Firstly, the on-chip resistor which is to be laser trimmed must be relatively large in order to give the laser an easy target to aim at. Secondly laser trimming must be done before the device is encapsulated in its package. Once the component (integrated circuit) has been laser trimmed, its accuracy may still not be fully guaranteed. This is because placing the component in the package, which is usually plastic, can cause further changes in the resistor accuracy and these cannot be trimmed out by the laser. During packaging the chip is normally immersed in the molten plastic that will form its package. The plastic exhibits thermal contraction as it cools and this places stress upon the semiconductor substrate forming the component. It is this stress which causes variations in the component values.

### SUMMARY OF THE INVENTION

According to a first aspect of the present invention there is provided a feedback circuit for an operational amplifier, the feedback circuit comprising a first impedance element in a current flow path between an output of the operational amplifier and a first node, and

a plurality of impedance elements which are, in response to a control signal, selectively connectable either between the first node and a first input of the operational amplifier, or between the first node and a further node, and the further node and the first input of the operational amplifier are at the same potential such that a voltage at the first node is independent of the control signal.

It is thus possible to provide a feedback circuit in which, assuming that the output voltage of the operational amplifier is held steady, changes to a switchable network of a plurality of impedance elements does not give rise to changes in voltage at an input node to the switchable network because, when viewed from the first node, the impedance of the switchable network from the first node to a reference voltage, usually ground, is unaffected by the configuration of the switchable network. This has the advantage that adjustments to the switchable network result in a linear and predictable change in the transfer characteristic of an amplifier associated with the feedback network.

Preferably the plurality of impedance elements within the switchable network are resistors. The resistors may be arranged to form a digital to analog converter core and, in this regard, an R-2R configuration is advantageous. The R-2R configuration has having a single input and each “2R” resistor extends from adjacent nodes of a series chain of “R” resistors to form an output node, and each output node is selectively connectable to either a first output or a second output of the switchable network. This ensures that, for a given voltage at an input node of the R-2R network, the current passing through the network does not depend on the digital code controlling the network provided that both the first and second outputs are held at a common voltage. The first and second outputs can be held at a shared voltage if they are connected to an operational amplifier as the action of the operational amplifier within a properly formed feedback loop is to hold the potential at its inverting and non-inverting inputs the same. Advantageously the operational amplifier is configured to operate in a “virtual earth” mode.

Advantageously an input, for example the inverting input, of the amplifier is arranged to receive a current from a circuit up-stream of the amplifier, and the feedback network around the amplifier causes the output of the amplifier to assume a voltage such that the entirety of the current can pass through the feedback network to the amplifier output. Thus the amplifier acts as a current to voltage converter.

Advantageously the current to voltage converter may be formed as an output stage within a digital to analog converter.

According to a second aspect of the present invention there is provided a current to voltage converter having an adjustable transfer characteristic, the converter comprising:
a first element having a first impedance and having first and second terminals;
a current steering device having a first, second and third terminals and controllable in response to a control signal to steer a proportion of a current flowing at the first terminal to the second terminal, and a remainder of the current to the third terminal thereof;
an operational amplifier having an output and an inverting input, and a feedback element having a second impedance connected between the output of the amplifier and the inverting input;
and wherein the first element and the current steering device are arranged in series between the output of the amplifier and the inverting input, and one of the second and third terminals is connected to the inverting input of the amplifier and, in use, the second and third terminals are held at the same voltage.

According to a third aspect of the present invention there is provided a digital to analog converter including a feedback network according to the first aspect of the present invention.

### BRIEF DESCRIPTION OF THE FIGURES

The present invention will further be described by way of example with reference to the accompanying drawings, in which:

FIG. 1 schematically illustrates a feedback circuit for an operational amplifier constituting an embodiment of the present invention;

FIG. 2 schematically illustrates a current steering arrangement, in the form of an R-2R ladder which is suitable for use in the feedback circuit of FIG. 1;

FIG. 3 illustrates an alternative current steering network in the form of a segmented R-2R ladder;

FIG. 4 is a schematic diagram showing an embodiment of the feedback network as incorporated within a monolithic integrated circuit;

FIG. 5 schematically illustrates a digital to analog converter including a current to voltage converter constituting an embodiment of the present invention; and

FIG. 6 schematically illustrates the amplifier gain as a function of trim code supplied to the trim network.

### DESCRIPTION OF PREFERRED EMBODIMENTS

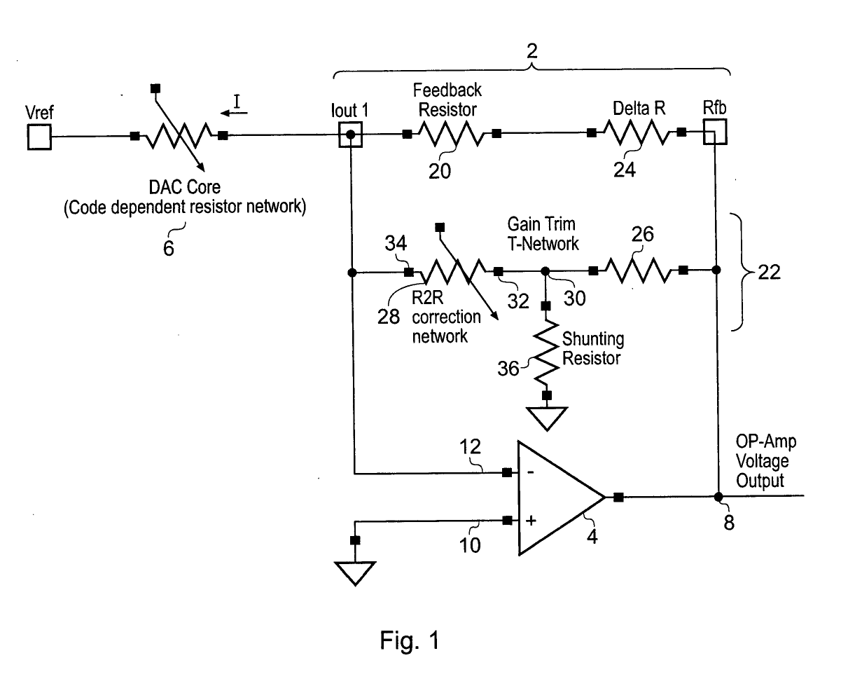

FIG. 1 schematically illustrates a feedback network constituting an embodiment of the present invention. The feedback network, generally designated 2, is associated with an operational amplifier 4. In the arrangement shown in FIG. 1 the operational amplifier 4 receives a current from a digital to analog converter 6 and the action of the operational amplifier 4 and its feedback network 2 is to convert the current from the digital to analog converter 6 into an output voltage at an output 8 of the operational amplifier 4. For simplicity of the description it is assumed that the digital to analog converter sinks a current, and hence current flows from the output of the amplifier and into the digital to analog converter via the feedback network. In practice it makes no difference whether the current is sunk by or flows from the input circuit (e.g. digital to analog converter) to the amplifier.

The operational amplifier 4 has a non-inverting input 10 and an inverting input 12. The non-inverting input 10 is generally held at a constant voltage, in this example ground voltage. In use, we can also assume that the voltage an the inverting input 12 of the operational amplifier will also be zero volts. The inverting input 12 is connected to an output terminal of the digital to analog converter 6.

In use, the circuit 6 sinks a current I which is to be converted into a voltage at the output 8 of the operational amplifier, given that no current (theoretically) flows into the non-inverting input 12 of the operational amplifier 4, we can assume that all of the current I must flow through the feedback network 2, and that the output voltage at the output 8 of the operational amplifier will assume whatever voltage is necessary in order to match the current flow through the feedback network 2 to be equal to the current flow to the device 6.

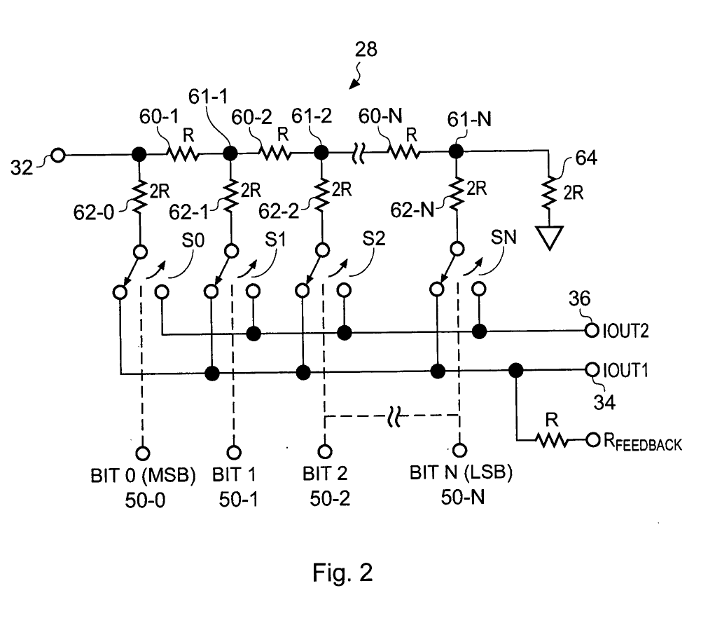

A conventional current to voltage converter would merely comprise a feedback resistor 20 connected between the output 8 of the operational amplifier 4 and its inverting input 12. The performance of the current to voltage converter would then be determined solely by the resistance of the feedback resistor 20. However, as explained above, in monolithically integrated circuits the act of packaging the circuit can create stresses upon the circuit which in turn can effect the value of components therein and can change the value of the feedback resistor 20 from its nominal value. The present invention overcomes this by providing a digitally controllable trimming network as part of the feedback network 2. This is implemented as a gain trimming network, generally designated 22, which is formed in parallel with the feedback resistor 20. The mere act of placing this trimming network 22 in parallel with the resistor 20 immediately reduces the impendence between the output 8 and the inverting input 12, and consequently a correction resistor 24 is added in series with the feedback resistor 20 so as to return the impedance to its nominal value. The trimming network 22 comprises a first impedance 26 in series with a current steering network 28. In this example the first impedance 26 is connected between an input terminal of the current steering network 28 and the output 8 of the operational amplifier. The current steering network, as will be explained in more detail later, effectively has an input terminal 32 connected to a node 30 formed between the network 32 and the first impedance 36 and has first and second output terminals, the first of which, designated 34, is connected to the inverting input 12 of the amplifier 4. The second output terminal, designated 36 and shown in FIG. 2, is connected to the same potential as the non-inverting input 10 of the amplifier 4. Such a current steering arrangement can be implemented by the R-2R ladder schematically illustrated in FIG. 2.

The feature of the current steering network 28 is that, although the proportion of the current passing from the input 32 to the first output 34 varies in accordance with a control word applied to the current steering network, the impedance of the network, when viewed from its input terminal 32, is invariant with respect to the control word that it receives. As a consequence, if the output voltage of the operational amplifier was held constant, then the voltage occurring at node 30 would also be constant irrespective of the control word supplied to the current steering network. The fact that the current steering network presents a constant impedance when viewed from node 30 means that the gain trim network 22 can trim the gain of the current to voltage converter in a consistent and predictable manner, and more importantly, that the step size of the gain adjustment is linear.

Advantageously a further resistor, in the form of a shunting resistor 36 extends between the first node 30 and the ground connection. It can be seen that the resistors 26 and the parallel combination of the resistor 36 and the current steering network 28 effectively forms a resistive potential divider and hence the value of the shunting resistor 36 can be used to set the step size of the gain correction applied by the current steering network 28.

FIG. 2 schematically illustrates an R-2R network. Such a network is commonly used as a digital to analog converter core where a reference voltage is provided at the input terminal 32, which results in a current flowing into the R-2R network, and then that current is divided between the first output 34 and the second output 36 in proportion to a digital control word presented to the digital control lines 50-0 to 50-N which control electronic switches S0 to SN within the converter core. The R-2R topology is well known to the person skilled in the art, but it can be seen to be composed at a string of resistors 60-1 to 60-N. The connections between the resistors define nodes 61-1 to 61-N and connected to each node 61-1 to 61-N is a further resistor 62-1 to 62-N having a value 2R which in turn connect to switches S1 to SN for steering current to the first output 34 or the second output 36. In this scheme, the node between the input 32 and the first resistor 60-1 is also connected to a resistor 62-0 having a value 2R which connects to switch S0 and the final node 61-N is terminated by a further resistor 64 having a value 2R which is connected to ground. It can be seen in this arrangement that the current flowing through the resistor 62-0 is twice the current flowing through the resistor 62-1, which in turn is twice the current flowing through the resistor 62-2, and so on. However, because the outputs 34 and 36 are both held at ground potential by the operation of the amplifier 4 forming a virtual earth, then it can be seen that the current drawn through the R-2R ladder is invariant of the states of the switches S0 to SN. This feature is particularly useful when forming the current steering network 28 because it means that current flow through the resistor 26 (FIG. 1) and the voltage at node 30 are not perturbed by the digital word controlling the current steering network 28 but that the proportion of the current that is admitted into the feedback loop via the first output 34 is dependent upon the digital word supplied to the current steering network 28.

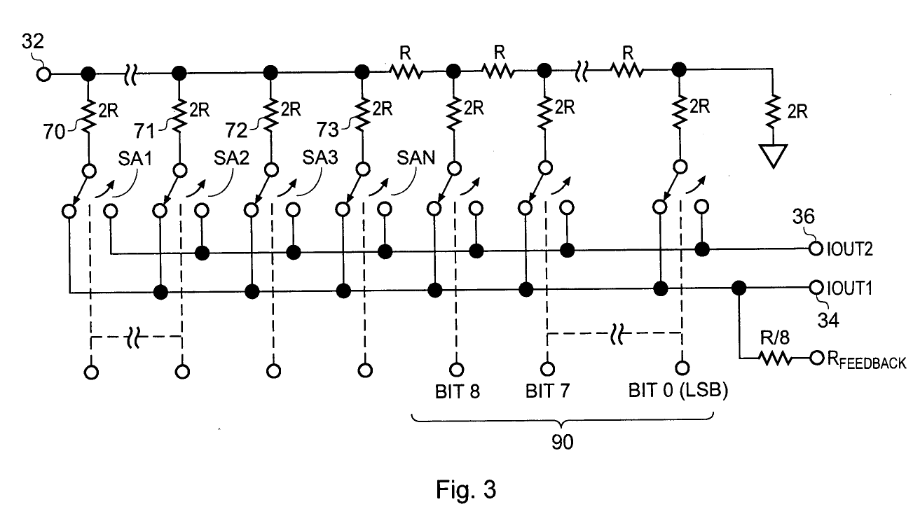

The R-2R ladder configuration shown in FIG. 2 is not the only way of performing current steering in a manner which presents a constant impedance at a notional input terminal. FIG. 3 shows an alternative configuration in which a plurality of current steering switches are effectively connected in parallel to the input node 32 via their respective resistors 70 to 73 and the current is steered to the first output 34 or the second output 36 dependent upon the state of the switches SA1 to SAN. As shown the resistors 70 to 73 have all been drawn as being the same size and hence this scheme is suitable for use with a thermometer decoding driving scheme. However it is also apparent that the resistors do not all have to be the same size and that they could, for example, be scaled in a binary weighted manner if desired. This scheme can be used alone or (as shown) in conjunction with a conventional R-2R ladder network, designated 90, if desired to form a digital to analog converter core or a current steering network (as appropriate) encoding a large number of bits.

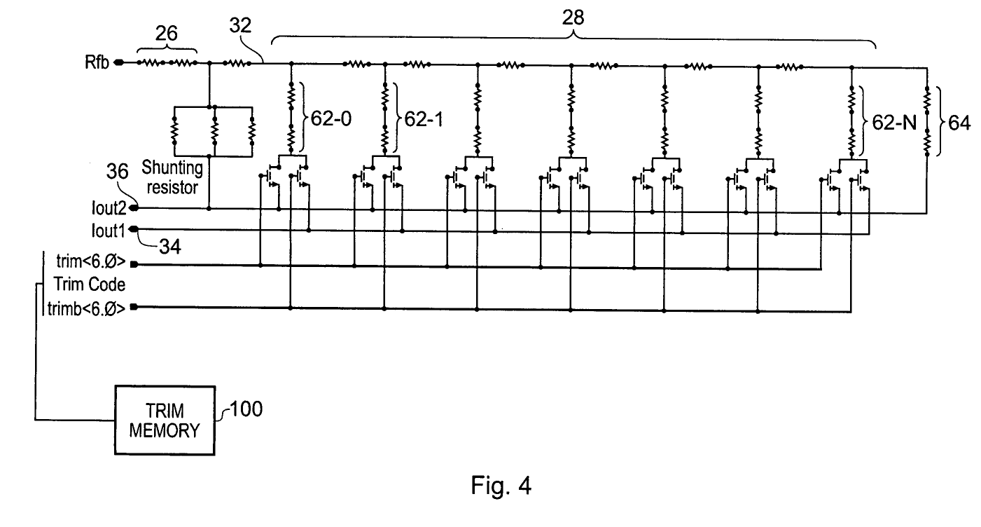

FIG. 4 schematically illustrates the representation of the trim network 22 suitable for implementation within a monolithic integrated circuit. It can be seen, in comparison with FIG. 1, that the shunting resistor 36 is formed by three unit value resistors in parallel, that the resistor 26 is formed by two unit value resistors in series, and that in the R-2R network 28 the resistors 62-0 to 62-N are formed by two unit value resistors arranged in series, as is the terminating resistor 64. It can also be seen that, as the second output 36 is connected to ground then the terminating resistor 64 can be connected to the second output 36. It can also be seen that, for ease of implantation, the change over switches S0 to SN are presented as pairs of field effect transistors, spanning between the respective end of the 2R resistor, and either the first output 34 or the second output 36, with the transistors receiving complimentary control signals such that, for each pair, one transistor is on whilst the other is off or vice versa.

In use, the control signals for the transistors within the R-2R ladder forming part of the current steering trim array are provided from a trim memory 100. After fabrication and encapsulation the performance of the current voltage converter/or gain of the feedback network is characterised and gain adjustment is effected by changing the trim code supplied to the various transistors within the current steering network. Once the performance of the feedback network, and hence the gain of the amplifier has been adjusted to an acceptable level of performance, the trim code is written into the trim memory. The trim memory may be a rewritable memory, and preferably a non-volatile rewritable memory, such as EEPROM, or it may be a write once non-volatile memory, for example formed by fuses which are blown in order to set the trim code permanently into the trim memory 100.

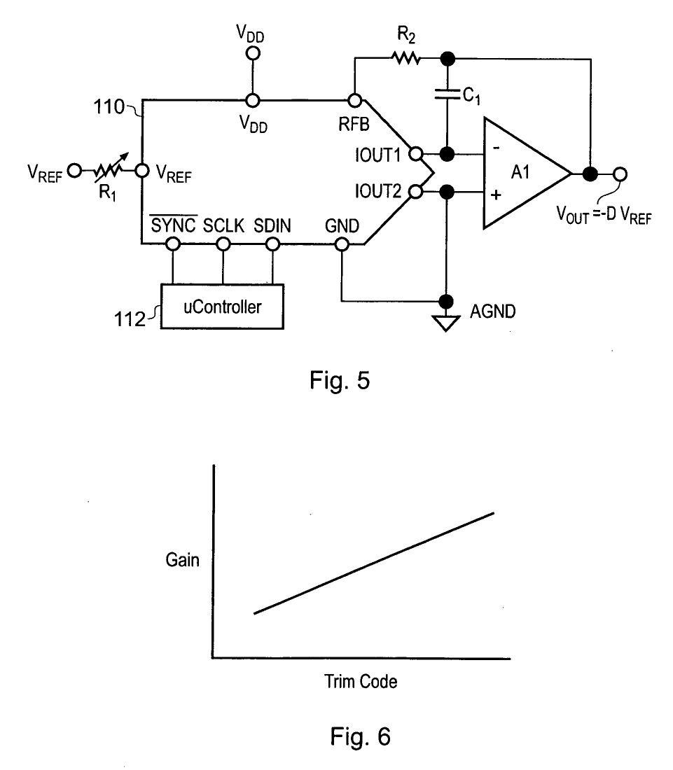

The current to voltage converter shown in FIG. 1 has utility at an output stage of a digital to analog converter. Such a converter is schematically shown in FIG. 5. The digital to analog converter shown in FIG. 5 is formed using a R-2R core of the type shown in FIG. 2 or 3, and therefore has outputs I_{OUT1} and I_{OUT2}. The converter is also provided with a pin, labelled RFB, which corresponds to the node labelled RFB in FIG. 1. Therefore the components 20, 24, and 22 shown in FIG. 1 can be integrated within the digital to analog converter 110 of FIG. 5. The operational amplifier 4 could also be integrated within the converter or, as shown in FIG. 5, can be provided as an external component. In use the microcontroller 112 controls the operation of the digital to analog converter and in particular loads the digital word which is to be converted. It should be noted that, if the user wishes to vary the gain of the converter from that determined by the manufacturer, they could introduce resistors R1 and R2 in the positions shown in order to provide a user definable gain. However, if the user is happy to accept the gain determined by the manufacturer, then the resistors R1 and R2 of FIG. 5 can be replaced by short circuit links.

Where the feedback network is, as shown in FIG. 5, being used in conjunction with a DAC core, then a FET switch may be placed in series with the feedback resistor 20 (see FIG. 1) and configured to be permanently on. This matches the thermal performance of the feedback network to that of the DAC core which also uses FET switches.

It is thus possible to provide a trimming feedback circuit suitable for use in a current to voltage converter wherein the current drawn by the trimming arrangement does not vary with a digital trim code, and consequently, as shown in FIG. 6, the gain of the current to voltage converter varies in a linear manner with respect to changes in the trim code.

1. A feedback circuit for an operational amplifier, the network comprising a first impedance element in a current flow path between an output of the operational amplifier and a first node; and
a plurality of impedance elements which are, in response to a control signal, selectively connectable either between the first node and a first input of the operational amplifier, or between the first node and a further node, and the further node and the first input of the operational amplifier are at the same potential such that a voltage at the first node is independent of the control signal.

2. A feedback circuit as claimed in claim 1, wherein the plurality of impedance elements are resistors.

3. A feedback circuit as claimed in claim 2, wherein at least some of the resistors are arranged in a R-2R ladder having multiple output nodes, each one of the output nodes being selectively connectable to the first input of the operational amplifier or to the further node.

4. A feedback circuit as claimed in claim 1, in which amplifier has a second input and the further node is connected to the second input.

5. A feedback circuit as claimed in claim 1, in which each of the plurality of impedance elements is associated with at least one electronically controllable switch for connecting the impedance element to either the first input of the amplifier or to the further node, and the switches are controllable in response to a digital control word.

6. A feedback circuit as claimed in claim 1, wherein the impedance from the first node to ground is independent of a value of the control signal.

7. A feedback circuit as claimed in claim 1, further comprising a feedback component connected between the amplifier output and its first input.

8. A feedback circuit as claimed in claim 1, further comprising a shunt connected between the first node and the further node.

9. A feedback circuit as claimed in claim 1, in which the plurality of impedance elements form a digitally controllable gain trimming circuit.

10. A feedback circuit as claimed in claim 1, in which the plurality of impedance elements form a digitally controllable current steering circuit.

11. A digital to analog converter including a feedback circuit as claimed in claim 1.

12. A current to voltage converter comprising an operational amplifier in combination with a feedback circuit as claimed in claim 1.

13. A current to voltage converter having an adjustable transfer characteristic, the converter comprising:
a first element having a first impedance and having first and second terminals;
a current steering device having a first, second and third terminals and controllable in response to a control signal to steer a proportion of a current flowing at the first terminal to the second terminal, and a remainder of the current to the third terminal thereof;
an operational amplifier having an output and an inverting input, and a feedback element having a second impedance connected between the output of the amplifier and the inverting input;
and wherein the first element and the current steering device are arranged in series between the output of the amplifier and the inverting input, and one of the second and third terminals is connected to the inverting input of the amplifier and, in use, the second and third terminals are held at the same voltage.

14. A digital to analog converter including a current to voltage converter as claimed in claim 13.
